(19) United States
(12) Patent Application Publication
(10) Pub. No.: US 2012/0013346 A1
(43) Pub. Date: Jan. 19, 2012

(54) SIGNAL TEST DEVICE FOR MOTHERBOARDS

(75) Inventors: LI XU, Shenzhen (CN); MING WEI, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 12/969,413

(22) Filed: Dec. 15, 2010

(30) Foreign Application Priority Data
Jul. 16, 2010 (CN) 201010229031.6

(51) Int. Cl. G01R 31/02

(52) U.S. Cl. 324/543

(57) ABSTRACT

A signal test device tests signal transmission performance of a DDR bus of a motherboard of a computer includes a connector, a checking module, and a number of signal collection units. The connector includes a number of connection pins. The checking module is electronically connected to the motherboard of the computer through the connection pins, and the checking module presets related a number of parameters of the DDR bus so that the motherboard can identify the signal test device. Each signal collection unit is electronically connected to the motherboard of the computer through the connection pins, and each signal collection unit includes a signal collection module. Each signal collection module provides a signal test point for collecting signals of the DDR bus.

### BACKGROUND

1. Technical Field

The disclosure generally relates to test devices, and more particularly relates to a test device for testing double data rate DDR) bus signals of motherboards.

2. Description of the Related Art

DDR type buses for computers have developed from DDR226 type to DDR3/1333 type, thus increasing its data transfer speed about 5 times. Meanwhile, impedance changes, signal interference, electro magnetic interference (EMI) and other interference factors influencing on DDR bus signals transmission are more obvious, so it is necessary to test signal transmission performance of the DDR bus.

However, most dynamic random access memory (DRAM) of a DDR memory module use fine-pitch ball grid array (FBGA) packaging, where the soldering spots of the DRAM are completely covered, so it is difficult to directly use an oscilloscope probe to test the signal transmission performance of the DDR bus. Therefore, extension lines are soldered on test points of the DDR memory module to connect a probe for testing. However, adding extension lines may easily affect the accuracy of signals, and soldering those extension lines on the intensive test points is also difficult and likely cause a short circuit.

Therefore, there is room for improvement within the art.

### BRIEF DESCRIPTION OF THE DRAWINGS

Many aspects of an exemplary signal test device can be better understood with reference to the following drawings. The components in the drawings are not necessarily drawn to scale, the emphasis instead being placed upon clearly illustrating the principles of the exemplary signal test device. Moreover, in the drawings, like reference numerals designate corresponding parts throughout the several views. Wherever possible, the same reference numbers are used throughout the drawings to refer to the same or like elements of an embodiment.

FIG. 1 is a block diagram of a signal test device, according to an exemplary embodiment.

FIG. 2 is a circuit view of one embodiment of a checking module and a connector of the signal test device as shown in FIG. 1.

FIG. 3 is a circuit view of one embodiment of a signal collection unit of the signal test device as shown in FIG. 1.

FIG. 4 is a simulation graph of signals tested by the signal test device as shown in FIG. 1.

### DETAILED DESCRIPTION

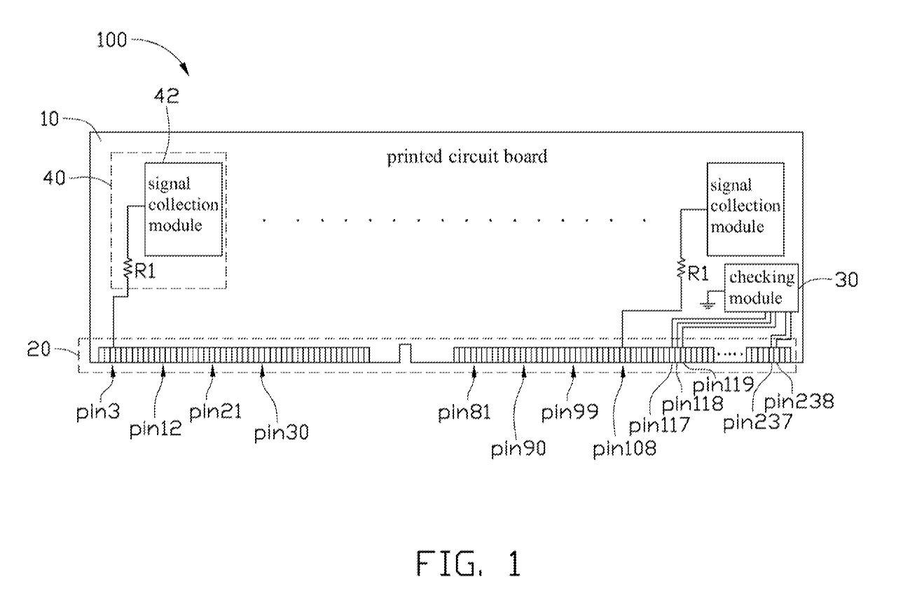

FIG. 1 shows a signal test device 100 for motherboards, according to an exemplary embodiment. The signal test device 100 is capable of simulating a DDR memory module in a computer for testing signal transmission performance of a DDR bus of a motherboard of the computer.

The signal test device 100 includes a printed circuit board (PCB) 10, a connector 20, a checking module 30, and a plurality of signal collection units 40. The connector 20, the checking module 30, and the plurality of signal collection units 40 are all integrated on the PCB 10.

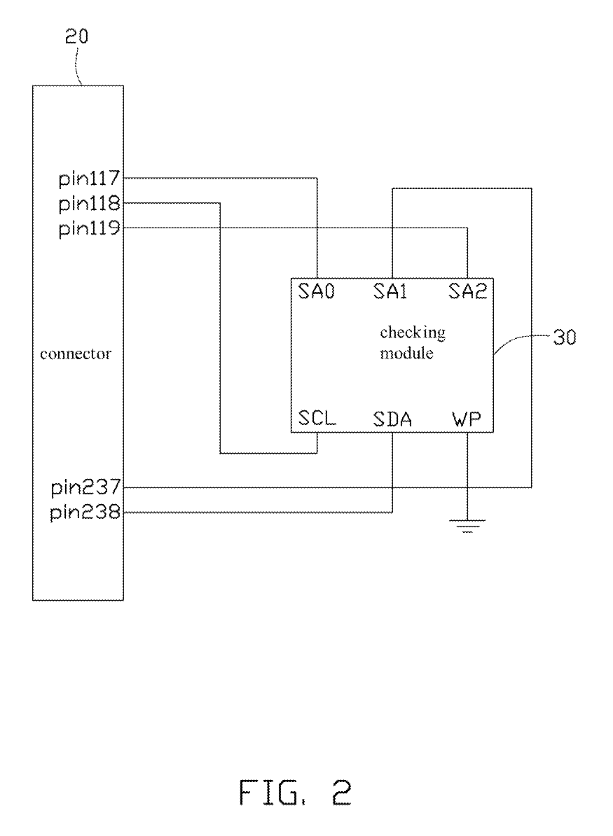

The connector 20 includes 240 connection pins, the connection pins are electronically connected to the motherboard of the computer when the signal test device 100 is inserted into a dual inline memory module (DIMM) of the computer. Among these connection pins, the connection pins 3, 12, 21, 30, 81, 90, 99, and 108 are respectively operable to receive data signals (For instance, DQ0, DQ8, DQ16, DQ24, DQ32, DQ40, DQ48, and DQ56) from the DDR bus of the motherboard, and send these data signals to the signal collection units 40. Referring to FIG. 2, the connection pins 117, 118, 119, 237, and 238 are operable to electronically connect to the checking module 30 and the DDR bus of the motherboard.

The checking module 30 is capable of simulating a serial presence detect (SPD) unit of the DDR memory module in the computer. The checking module 30 has been used to write transfer rate, capacity, voltage, row/column address, bandwidth, and other related parameters in advance. The checking module 30 includes address pins SA0-SA2, a clock pin SCL, a data pin SDA, and a ground pin WP. The address pins SA0-SA2 are respectively connected to the connection pins 117, 237, and 119 of the connector 20 for sending address signals to the motherboard of the computer. The clock pin SCL and the data pin SDA are respectively connected to the connection pin 118 and the connection pin 238 for sending clock signals and serial data signals to the motherboard of the computer. The ground pin WP is connected to ground. When the computer has been powered on and the signal test device 100 is inserted into the DIMM, the motherboard of the computer can read the parameters of the checking module 30 through the address pin SA0-SA2, the clock pin SCL, and the data pin SDA. Thus, the motherboard of the computer can identify the signal test device 100.

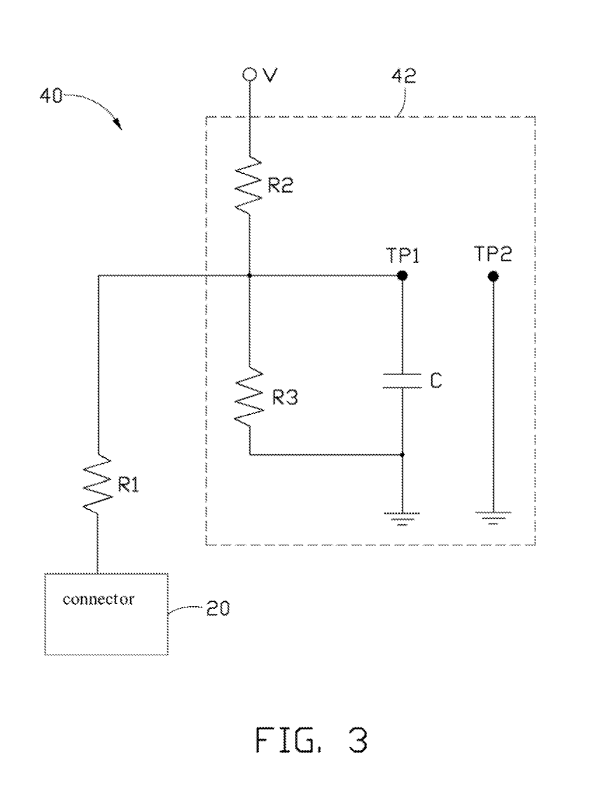

Also referring to FIG. 3, each signal collection unit 40 is capable of testing signal transmission performance of the DDR bus. In this exemplary embodiment, the number of the signal collection units 40 is eight, each signal collection unit 40 includes a signal collection module 42 and a first resistor R1. The signal collection module 42 includes a second resistor R2, a third resistor R3, a capacitor C, a signal test point TP1, and a ground test point TP2.

The second resistor R2 and the third resistor R3 are electronically connected in series between a power supply V and ground. The power supply V is capable of supplying 1.5 volts (in one example) to the signal collection module 42. The capacitor C is electronically connected to the third resistor R3 in parallel. In this exemplary embodiment, the second resistor R2 and the third resistor R3 are 220 ohms and 340 ohms, respectively, and both are operable to simulate signal receiving effect of the DRAM. The capacitor C can be about 1.3 pF which can simulate a parasitic capacitance of the DRAM. The signal test point TP1 is set between the second resistor R2 and the capacitor C. The ground test point TP2 is connected to ground. Each end of the eight first resistors R1 are respectively connected to the connection pins 3, 12, 21, 30, 81, 90, 99, 108 of the connector 20, and another end of the eight first resistors R1 are respectively connected between the second resistor R2 and the third resistor R3 of a corresponding signal collection module 42. The first resistor R1 can match impedance between a signal line of the motherboard and a signal line of the signal test device 100 to protect the signal transmission performance of the DDR bus from interfering. In this exemplary embodiment, the first resistor is about 20 ohm.

For testing the signal transmission performance of the DDR bus, firstly, the computer is started and the signal test device 100 is inserted into the DIMM. The motherboard of the computer automatically reads the parameters wrote in the checking module 30 in advance, and identifies the signal test device 100. Secondly, an oscilloscope or other waveform test devices, test the signals of the DDR bus. The signal test point TP1 is connected to a signal pin of the oscilloscope, and the ground test point TP2 is connected to a ground pin of the oscilloscope. Thus, the oscilloscope can collect data signals of DQ0 of the DDR bus through the connector 20. Similarly, by selecting the signal test point TP1 of the different signal collection units 40, the signal test device 100 can test other data signals of DQ8, DQ16, DQ24, DQ32, DQ40, DQ48, and DQ56 of the DDR bus.

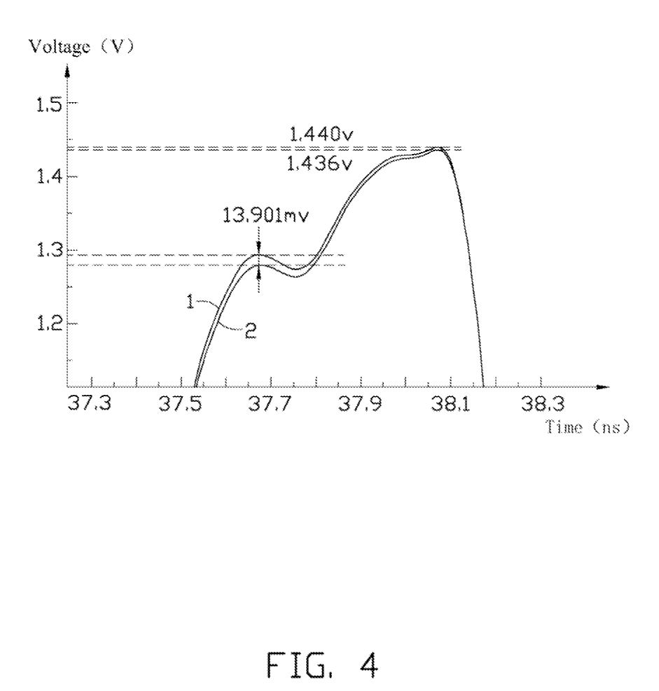

Further referring to FIG. 4, curve 1 is an oscillogram collected by the DDRM of the DDR memory module, and curve 2 is an oscillogram collected by the signal test device 100. With the same input signals, the maximum output voltage collected by the DRAM is 1.440V, and the maximum output voltage collected by signal test device 100 is 1.436V, and the maximum difference of the two output voltages of the curve 1 and the curve 2 is about 13.9 mV. Thus, the error of the signal test device 100 is less than 1%(13.9 Mv/1.436V=0.97%).

The signal test device 100 can simulate the DDR memory module of the computer, and collect data signals of the DDR bus through the collection module 20. Moreover, the signal test device 100 is high accuracy and convenient through testing the signal test point TP1 and the ground test point TP2.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in matters of shape, size, and arrangement of parts within the principles of exemplary disclosure to the full extent indicated by the broad general meaning of the terms in which the appended claims are expressed.

What is claimed is:

1. A signal test device for testing signal transmission performance of a DDR bus of a motherboard of a computer, comprising:
a connector including a plurality of connection pins;
a checking module; and
a plurality of signal collection units, each signal collection unit including a signal collection module; each signal collection module providing a signal test point for collecting signals of the DDR bus;
wherein the checking module and the plurality of signal collection units are all electronically connected to the motherboard of the computer through the connection pins, and the checking module predetermines a plurality of parameters of the DDR bus so that the motherboard can identify the signal test device.

2. The signal test device as claimed in claim 1, wherein each signal collection unit further includes a first resistor electronically connected between the signal collection module and the connector, wherein the first resistor is operable to match impedance between the motherboard of the computer and the signal test device.

3. The signal test device as claimed in claim 1, wherein each signal collection module provides a ground test point for connecting to ground.

4. The signal test device as claimed in claim 2, wherein each signal collection module includes a second resistor, a third resistor, and a capacitor, the second resistor and the third resistor are electronically connected in series between a power supply and ground, and the capacitor connected to the third resistor in parallel.

5. The signal test device as claimed in claim 4, wherein the second resistor and the third resistor are capable of simulating signal receiving effect of a DRAM of DDR bus, and the capacitor is capable of simulating a parasitic capacitance of the DRAM.

6. The signal test device as claimed in claim 4, wherein one end of the first resistor is electronically connected between the second resistor and the third resistor, and the other end is connected to a corresponding connection pin.

7. The signal test device as claimed in claim 4, wherein the signal test point is positioned between the second resistor and the capacitor.

8. The signal test device as claimed in claim 1, wherein the checking module is capable of simulating a serial presence detect unit, and the checking module has been used to write transfer rate, capacity, voltage, row/column address, and bandwidth in advance.

9. The signal test device as claimed in claim 1, wherein the checking module includes a set of address pins, a clock pin, a data pin, and a ground pin, the address pins are electronically connected to the connector for sending address signals to the motherboard of the computer, the clock pin and the data pin are connected to the connector for sending clock signals and serial data signals to the motherboard, the ground pin is connected to ground.

10. A signal test device for testing signal transmission performance of a DDR bus of a motherboard of a computer, comprising:
a printed circuit board;
a connector including a plurality of connection pins;
a checking module; and
a plurality of signal collection units, each signal collection unit including a signal collection module; each signal collection module providing a signal test point for collecting signals of the DDR bus;
wherein the connector, the checking module and the collection units are all integrated on the printed circuit board; the connector includes a plurality of connection pins; the checking module and the plurality of signal collection units are all electronically connected to the motherboard of the computer through the connection pins, and the checking module predetermines a plurality of parameters of the DDR bus to be identified by the motherboard.

11. The signal test device as claimed in claim 10, wherein the signal collection module further includes a ground test point, the ground test point is connected to the ground.

12. The signal test device as claimed in claim 10, wherein each signal collection unit includes a first resistor electronically connected between the signal collection module and the connector, wherein the first resistor is operable to match an impedance between the motherboard of the computer and the signal test device.

13. The signal test device as claimed in claim 12, wherein each signal collection module includes a second resistor, a third resistor, and a capacitor, the second resistor and the third resistor are electronically connected in series between a power supply and ground, and the capacitor connected to the third resistor in parallel.

14. The signal test device as claimed in claim 13, wherein one end of the first resistor is electronically connected between the second resistor and the third resistor, and the other end is connected to a corresponding connection pin.

15. The signal test device as claimed in claim 10, wherein the signal test point is positioned between the second resistor and the capacitor.

16. The signal test device as claimed in claim 10, wherein the checking module includes a set of address pins, a clock pin, a data pin, and a ground pin, the address pins are electronically connected to the connector for sending address signals to the motherboard of the computer, the clock pin and the data pin are connected to the connector for sending clock signals and serial data signals to the motherboard, the ground pin is connected to ground.

17. The signal test device as claimed in claim 10, wherein the signal test device is capable of inserting into a dual inline memory module of the motherboard of the computer.
